(19) United States
(12) Patent Application Publication
(10) Pub. No.: US 2026/0259255 A1
(43) Pub. Date: Sep. 3, 2026

(54) POWER GRID FAULT DIAGNOSIS METHOD BASED ON TIME CONSTRAINTS AND IMPROVED TIME-CONVNEXT NETWORK

(71) Applicants: Hainan Research Institute of Zhejiang University, Sanya (CN); Zhejiang University, Hangzhou (CN)

(72) Inventors: Xianbo WANG, Sanya (CN); Yunfeng YAN, Sanya (CN); Donglian QI, Sanya (CN); Changpeng WANG, Sanya (CN); Pengzhan XU, Sanya (CN); Siqi ZHANG, Sanya (CN)

(73) Assignees: Hainan Research Institute of Zhejiang University, Sanya (CN); Zhejiang University, Hangzhou (CN)

(21) Appl. No.: 19/406,997

(22) Filed: Dec. 3, 2025

(30) Foreign Application Priority Data
Mar. 3, 2025 (CN) 202510240808.5

(51) Int. Cl. G01R 31/08

(52) U.S. Cl. CPC G01R 31/088; G01R 31/086; H02J 3/001; H02J 13/12

(57) ABSTRACT

A power grid fault diagnosis method based on time constraints and an enhanced Time-ConvNeXt network includes: extracting and screening key features from a power grid fault alarm text, generating an alarm event encoding matrix, and incorporating a time-dependent exponentially decaying weight, thereby obtaining a temporal encoding matrix; incorporating a recurrent sequential attention into a ConvNeXt network, thereby obtaining an improved Time-ConvNeXt network, and inputting the temporal encoding matrix for end-to-end training of a power grid fault diagnosis model, thereby extracting spatiotemporal features; and inputting a test set into a trained power grid fault diagnosis model, and outputting a probability value of a power grid fault type via a fully connected layer. The method achieves efficient fusion of temporal features during power grid fault diagnosis, further improving both the efficiency and accuracy of the power grid fault diagnosis.

### CROSS REFERENCE TO THE RELATED APPLICATIONS

This application is based upon and claims priority to Chinese Patent Application No. 202510240808.5, filed on Mar. 3, 2025, the entire contents of which are incorporated herein by reference.

### TECHNICAL FIELD

The present invention relates to the technical field of power grid fault diagnosis in smart grids, and particularly, to a power grid fault diagnosis method based on time constraints and an enhanced Time-ConvNeXt network.

### BACKGROUND

With the rapid development of smart grids, demands for accuracy and real-time performance in power grid fault diagnosis are increasing. Conventional fault diagnosis methodologies predominantly rely on expert systems and fuzzy Petri nets, exhibiting limitations including: reliance on manual expertise, slow diagnostic speed, and inability to effectively handle complex multi-fault scenarios. Moreover, conventional methods fail to adequately utilize temporal information, resulting in compromised diagnostic accuracy and robustness when confronted with dynamically changing power grid faults.

Current power grid fault diagnosis models are typically based on electrical quantities and switching signals data, but fail to adequately exploit the spatiotemporal correlation features inherent in alarm information. For example, alarm data provided by supervisory control and data acquisition (SCADA) systems contains a significant amount of redundant information. Conventional methods struggle to effectively filter out interference and fail to incorporate the time constraints associated with historical fault events into the model design. Although deep learning techniques (such as convolutional neural networks), have been introduced into the field of fault diagnosis in recent years, existing models still lack the capability to efficiently integrate temporal features, limiting the applicability in real-time diagnostic applications.

Accordingly, what is needed in the art and constitutes a pressing problem for those skilled in the art is a power grid fault diagnosis method based on time constraints and an improved Time-ConvNeXt network. The method can implement efficient fusion of temporal features during the power grid fault diagnosis process, thereby further improving the efficiency and accuracy of power grid fault diagnosis.

### SUMMARY

In view of the foregoing, the present invention proposes a power grid fault diagnosis method based on time constraints and an improved Time-ConvNeXt network.

To achieve the above objective, the present invention adopts the following technical solution.

A power grid fault diagnosis method based on time constraints and an improved Time-ConvNeXt network, including:
S1. extracting and screening key features from a power grid fault alarm text, generating an alarm event encoding matrix, and incorporating a time-dependent exponentially decaying weight, thereby obtaining a temporal encoding matrix;
S2. incorporating a recurrent sequential attention into a ConvNeXt network, thereby obtaining an improved Time-ConvNeXt network, and inputting the temporal encoding matrix for end-to-end training of a power grid fault diagnosis model, thereby extracting spatiotemporal features; and
S3. inputting a test set into a trained power grid fault diagnosis model, and outputting a probability value of a power grid fault type via a fully connected layer.

Optionally, in step (1), extracting and screening the key features from the power grid fault alarm text based on a maximum relevance minimum redundancy criterion.

Optionally, in step (1), the generated alarm event encoding matrix is as follows:

$${D}_{A} = [ \begin{matrix}{a}_{11} & ⋯ & {a}_{1 y} \\ ⋯ & {a}_{ij} & ⋯ \\ {a}_{x 1} & ⋯ & {a}_{xy}\end{matrix} ] ;$$

wherein D_{A} is an alarm event encoding matrix, a denotes an encoded value of a feature at row i and column j of the alarm event, and a priority level decreases from top-left to bottom-right.

Optionally, in step (1), the time-dependent exponentially decaying weight is as follows:

$${w}_{decay} ( t ) = {e}^{- α t} ;$$

$$t = \vert {T}_{current} - {T}_{past} \vert ;$$

wherein Tₚₐₛₜ denotes a timestamp of a historical alarm event; T_{current} denotes a timestamp of a current alarm event; t denotes a time difference between the historical alarm event and the current alarm event; w_{decay}(t) denotes a weight value assigned to the historical alarm event; and a denotes an attenuation factor configured to control an influence degree of the time difference on the weight value.

Optionally, in step (1), the temporal encoding matrix is as follows:

$${D}_{A} ( t ) = [ \begin{matrix}{a}_{11} & ⋯ & {a}_{1 y} \\ ⋯ & {a}_{ij} & ⋯ \\ {a}_{x 1} & ⋯ & {a}_{xy}\end{matrix} ] ⊙ {w}_{decay} ( t ) ;$$

wherein D_{A}(t) denotes a temporal encoding matrix; aᵢⱼ denotes the encoded value of a feature at row i and column j of the alarm event, and the priority level decreases from top-left to bottom-right; and w_{decay}(t) denotes the weight value assigned to the historical alarm event.

Optionally, in step (2), the incorporating a recurrent sequential attention into a ConvNeXt network specifically includes:
assigning channel attention weights by global average pooling and a fully connected layer, specifically including:
performing global average pooling on the input features to obtain a feature representation with reduced spatial dimensions, which is configured to further extract channel-wise features, then transforming through the fully connected layer, thereby obtaining attention weights for each channel, as follows:

$${W}_{d s} = F C ( GAP ( F ) ) ;$$

wherein W_{ds} denotes attention weights for each channel; F denotes an input feature tensor; GAP denotes a global average pooling operation, configured to obtain global average values for each channel; and FC denotes a fully connected layer configured to transform the global average values into the attention weights for each channel;
employing a residual mechanism to iteratively update features, specifically including:
multiplying the attention weights with input features, adding a resulting product to the original input features to form a residual connection, and repeating the updating process R times, as follows:

$${F}_{ds} = F + F ⊙ {W}_{ds} ;$$

$${F}_{ds} = {update ( F )}_{i} , for i ∈ R ;$$

wherein F_{ds} denotes an updated feature tensor; (denotes element-wise multiplication; and
   update denotes performing a cyclic updating operation.

Optionally, in step (2), the improved Time-ConvNeXt network includes depthwise separable convolution, layer normalization and a gaussian error linear unit (GELU) activation function.

Optionally, the depthwise separable convolution decomposes a standard convolution into a depthwise convolution and a pointwise convolution.

Optionally, the GELU activation function is as follows:

$$GELU ( x ) = 0.5 \cdot x \cdot ( 1 + tanh ( \sqrt{\frac{2}{π}} \cdot ( x + 0.044715 {x}^{3} ) ) ) ;$$

wherein GELU(x) denotes an output of a GELU activation function; x denotes an input of the GELU activation function; and tanh denotes a hyperbolic tangent function.

Optionally, the method further includes employing a cross-entropy as a loss function of the power grid fault diagnosis model.

As evidenced by the foregoing technical solution, compared with the prior art, the present invention provides a power grid fault diagnosis method based on time constraints and an improved Time-ConvNeXt network. By incorporating time decay weights and temporal difference features, an encoding matrix is augmented to integrate the temporal dependencies of historical fault events.

Further, a recurrent sequential attention (RSE) module is integrated into the ConvNeXt network, enhancing the model's capability to capture temporal fault features, thereby achieving efficient fusion of temporal features during power grid fault diagnosis, further improving both the efficiency and accuracy of the power grid fault diagnosis.

### BRIEF DESCRIPTION OF THE DRAWINGS

In order to describe the technical solutions in the embodiments of the present invention or the prior art more clearly, the accompanying drawings required in the descriptions of the embodiments or the prior art are briefly introduced below. It is to be noted that the accompanying drawings described below illustrate only the embodiments of the present invention. Other drawings may be obtained by a person of ordinary skill in the art from the accompanying drawings without any creative efforts.

FIG. 1 is a flowchart of a method according to the present invention.

FIG. 2 is a schematic diagram illustrating a structure of an improved Time-ConvNeXt network according to the present invention.

### DETAILED DESCRIPTION OF THE EMBODIMENTS

In the following, the technical solutions in the embodiments of the present invention are clearly and completely described with reference to the drawings in the embodiments of the present invention. It is to be noted that the described embodiments are only a part of the embodiments of the present invention, but not all the embodiments thereof. Based on the embodiments of the present invention, all other embodiments obtained by those skilled in the art without any creative efforts shall fall within the protection scope of the present invention.

### Embodiment 1

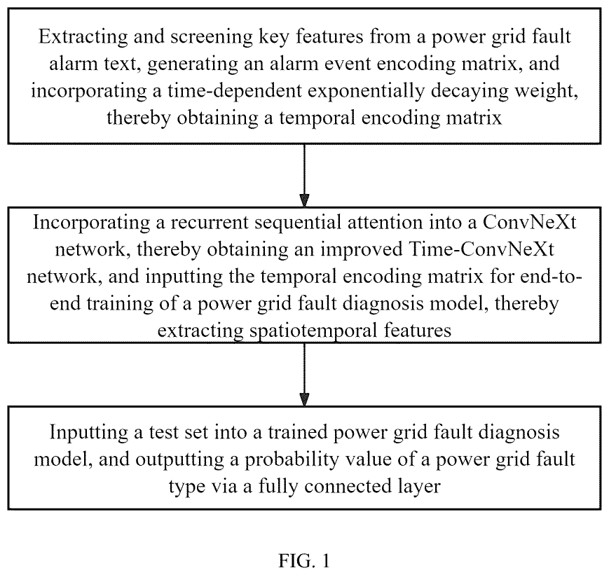

The embodiment of the present invention discloses a power grid fault diagnosis method based on time constraints and an improved Time-ConvNeXt network, as shown in FIG. 1, including:
S1. Key features are extracted and screened from a power grid fault alarm text, an alarm event encoding matrix is generated, and a time-dependent exponentially decaying weight is incorporated, thereby obtaining a temporal encoding matrix.

The grid fault alarm text is obtained from an SCADA system, with standardization processing performed on the text prior to key feature extraction.

The key features in the power grid fault alarm text are extracted and screened based on a maximum relevance minimum redundancy (mRMR) criterion.

The generated alarm event encoding matrix is as follows:

$${D}_{A} = [ \begin{matrix}{a}_{11} & ⋯ & {a}_{1 y} \\ ⋯ & {a}_{ij} & ⋯ \\ {a}_{x 1} & ⋯ & {a}_{xy}\end{matrix} ] ;$$

wherein D_{A} is an alarm event encoding matrix, aᵢⱼ denotes an encoded value of a feature at row i and column j of the alarm event, and a priority level decreases from top-left to bottom-right.

To cause the influence of historical events on a current event to decay over time, the weights of the historical events are adjusted within the encoding matrix, and the time-dependent exponentially decaying weight is incorporated, as follows:

$${w}_{decay} ( t ) = {e}^{- α t} ;$$

$$t = \vert {T}_{c urrent} - {T}_{past} \vert ;$$

wherein Tₚₐₛₜ denotes a timestamp of a historical alarm event; T_{current} denotes a timestamp of a current alarm event; t denotes a time difference between the historical alarm event and the current alarm event; w_{decay}(t) denotes a weight value assigned to the historical alarm event; and a denotes an attenuation factor configured to control an influence degree of the time difference on the weight value.

The temporal encoding matrix is as follows:

$${D}_{A} ( t ) = [ \begin{matrix}{a}_{11} & ⋯ & {a}_{1 y} \\ ⋯ & {a}_{ij} & ⋯ \\ {a}_{x 1} & ⋯ & {a}_{xy}\end{matrix} ] ⊙ {w}_{decay} ( t ) ;$$

wherein D_{A}(t) denotes a temporal encoding matrix; aᵢⱼ denotes the encoded value of a feature at row i and column j of the alarm event, and the priority level decreases from top-left to bottom-right; and w_{decay}(t) denotes the weight value assigned to the historical alarm event.
S2. A recurrent sequential attention (RSE) module is incorporated into a ConvNeXt network, thereby obtaining an improved Time-ConvNeXt network, and the temporal encoding matrix is input for end-to-end training of a power grid fault diagnosis model, thereby extracting spatiotemporal features.

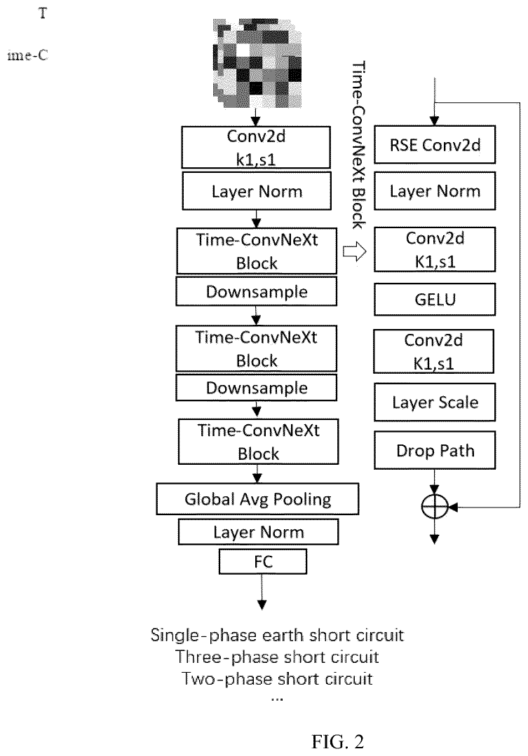

The Time-ConvNeXt network is shown in FIG. 2.

The RSE module is incorporated into the ConvNeXt network, specifically including:
channel attention weights are assigned through global average pooling (GAP) and a fully connected layer (FC), specifically including:
the global average pooling is performed on the input features to obtain a feature representation with reduced spatial dimensions, which is configured to further extract channel-wise features, followed by transforming through the fully connected layer, thereby obtaining attention weights for each channel, as follows:

W_{ds}=FC(GAP(F));
wherein W_{ds} denotes attention weights for each channel; F denotes an input feature tensor; GAP denotes a global average pooling operation, configured to obtain global average values for each channel; and FC denotes a fully connected layer configured to transform the global average values into the attention weights for each channel;
a residual mechanism is employed to iteratively update features, which can effectively enhance he capability to capture temporal dependencies. Furthermore, the residual connection design not only mitigates the gradient vanishing problem but also effectively integrates the original input information with features modulated by attention weights, thereby enhancing the model's capability for feature transmission and learning. The residual mechanism is employed to iteratively update features, specifically including:

the attention weights are multiplied with input features, then a resulting product is added to the original input features to form a residual connection, and the updating process is repeated R times, as follows:

$${F}_{ds} = F + F ⊙ {W}_{ds} ;$$

$${F}_{ds} = {update ( F )}_{i} , for i ∈ R ;$$

wherein F_{ds} denotes an updated feature tensor; (denotes element-wise multiplication; and
   update denotes performing a cyclic updating operation. Repeating the updating process R times enhances the capability to understand faults occurring at different time points and to represent relationships between features and time. Moreover, the cyclic processing mechanism enables iterative refinement of temporal information by the model, thereby enhancing capture of long-term dependencies across sequential data.

The improved Time-ConvNeXt network includes depthwise separable convolution, layer normalization and a GELU activation function.

The depthwise separable convolution, an essential component of the ConvNeXt network, is implemented by decomposing a standard convolution into a pointwise convolution (1×1 convolution) and a depthwise convolution (3×3 convolution). The decomposition reduces computational load while enhancing operational efficiency of the network. Local and global information of features is effectively extracted by the depthwise separable convolution.

Features are processed through depthwise separable convolution, followed by normalization of the features through layer normalization (LayerNorm). The layer normalization stabilizes the training process of models, mitigates internal covariate shift issues, and enhances model robustness and convergence rate.

Finally, the GELU activation function is employed as a non-linear activation unit. The GELU activation function is a smooth activation function. The GELU activation function is as follows:

$$GELU ( x ) = 0.5 \cdot x \cdot ( 1 + tanh ( \sqrt{\frac{2}{π}} \cdot ( x + 0.044715 {x}^{3} ) ) ) ;$$

wherein GELU(x) denotes an output of a GELU activation function; x denotes an input of the GELU activation function; and tanh denotes a hyperbolic tangent function.
S3. A test set is input into a trained power grid fault diagnosis model, and a probability value of a power grid fault type is output via the fully connected layer.

The method further includes a cross-entropy is employed as a loss function of the power grid fault diagnosis model.

The embodiment of the present invention discloses a power grid fault diagnosis method based on time constraints and an improved Time-ConvNeXt network. In terms of accuracy, the time-constrained encoding matrix employed by the present invention enhances the model's adaptability to dynamic faults by quantifying temporal correlations among historical events. The RSE module captures long-term temporal dependencies through a recurrent attention mechanism, thereby enhancing discrimination accuracy in complex fault scenarios. The innovation achieves an accuracy (ACC) of 97.7% on the test set, representing an improvement of 11.2% compared with conventional ResNet methods. In terms of real-time performance, the end-to-end design adopted by the present invention reduces intermediate processing steps, shortening the single diagnosis time to the millisecond level, which can satisfy the real-time fault diagnosis requirements of modern smart grids, thereby significantly enhancing grid operational efficiency and reliability. In terms of robustness, the time decay mechanism employed in the present invention effectively suppresses redundant alarm interference, elevating the F1-score to 95.2%, which demonstrates that the invention maintains high diagnostic accuracy and stability when handling complex multi-fault scenarios, thereby substantially enhancing model robustness. In terms of reliance on expert knowledge, the present invention reduces such reliance by automatically extracting features and temporal dependencies, thereby mitigating subjective errors during diagnosis and enhancing the objectivity and consistency of diagnostic results. In terms of feature extraction, the improved Time-ConvNeXt network employed in the present invention combines depthwise separable convolution and a recurrent sequential attention module, achieving efficient spatiotemporal feature extraction, which enables the model to rapidly and accurately identify fault types when processing large-scale power grid data, thereby significantly improving diagnostic efficiency.

Each embodiment in the description is described in a progressive manner, and each embodiment focuses on its differences from other embodiments. The same and similar parts of each embodiment can be referred to each other. For the device disclosed by the embodiment, the description is relatively simple because it corresponds to the method disclosed by the embodiment, and the relevant information can be referred to the method section.

The above description of the disclosed embodiments enables those skilled in the art to implement or use the present disclosure. Various amendments to the embodiments are apparent to those skilled in the art. The general principles defined herein may be implemented in other embodiments without departing from the spirit or scope of the disclosure. Therefore, the present disclosure will not be limited to the embodiments shown herein but is to be accorded the widest scope consistent with the principles and novel features disclosed herein.

What is claimed is:

1. A power grid fault diagnosis method based on time constraints and an improved Time-ConvNeXt network, comprising the following steps:
S1: extracting and screening key features from a power grid fault alarm text, generating an alarm event encoding matrix, and incorporating a time-dependent exponentially decaying weight, thereby obtaining a temporal encoding matrix;
S2: incorporating a recurrent sequential attention into a ConvNeXt network, thereby obtaining the improved Time-ConvNeXt network, and inputting the temporal encoding matrix for end-to-end training of a power grid fault diagnosis model, thereby extracting spatiotemporal features; and
S3: inputting a test set into a trained power grid fault diagnosis model, and outputting a probability value of a power grid fault type via a fully connected layer;
wherein in the step S1, the time-dependent exponentially decaying weight is as follows:
$${w}_{decay} ( t ) = {e}^{- α t} ;$$
$$t = \vert {T}_{c urrent} - {T}_{past} \vert ;$$
wherein Tₚₐₛₜ denotes a timestamp of a historical alarm event; T_{current} denotes a timestamp of a current alarm event; t denotes a time difference between the historical alarm event and the current alarm event; w_{decay}(t) denotes a weight value assigned to the historical alarm event; and a denotes an attenuation factor configured to control an influence degree of the time difference on the weight value; and
wherein in the step S2, the incorporating the recurrent sequential attention into the ConvNeXt network comprises:
assigning channel attention weights by global average pooling and the fully connected layer, comprising:
performing the global average pooling on input features to obtain a feature representation with reduced spatial dimensions, wherein the feature representation is configured to further extract channel-wise features, and then transforming through the fully connected layer, thereby obtaining attention weights for each channel, as follows:
$${W}_{d s} = F C ( GAP ( F ) ) ;$$
wherein W_{ds} denotes the attention weights for each channel; F denotes an input feature tensor; GAP denotes a global average pooling operation, configured to obtain global average values for each channel; and FC denotes the fully connected layer configured to transform the global average values into the attention weights for each channel; and
employing a residual mechanism to iteratively update features, comprising:
multiplying the attention weights with the input features, adding a resulting product to original input features to form a residual connection, and repeating an updating process R times, as follows:
$${F}_{ds} = F + F ⊙ {W}_{ds} ;$$
$${F}_{ds} = {update ( F )}_{i} , for i ∈ R ;$$
wherein F_{ds} denotes an updated feature tensor; ⊙ denotes element-wise multiplication; and update denotes performing a cyclic updating operation.

2. The power grid fault diagnosis method based on the time constraints and the improved Time-ConvNeXt network according to claim 1, wherein in the step S1, the key features from the power grid fault alarm text are extracted and screened based on a maximum relevance minimum redundancy criterion.

3. The power grid fault diagnosis method based on the time constraints and the improved Time-ConvNeXt network according to claim 1, wherein in the step S1, the alarm event encoding matrix is as follows:
$${D}_{A} = [ \begin{matrix}{a}_{11} & ⋯ & {a}_{1 y} \\ ⋯ & {a}_{ij} & ⋯ \\ {a}_{x 1} & ⋯ & {a}_{xy}\end{matrix} ] ;$$
wherein D_{A} is the alarm event encoding matrix, aᵢⱼ denotes an encoded value of a feature at row i and column j of an alarm event, and a priority level decreases from top-left to bottom-right.

4. The power grid fault diagnosis method based on the time constraints and the improved Time-ConvNeXt network according to claim 1, wherein in the step S1, the temporal encoding matrix is as follows:
$${D}_{A} ( t ) = [ \begin{matrix}{a}_{11} & ⋯ & {a}_{1 y} \\ ⋯ & {a}_{ij} & ⋯ \\ {a}_{x 1} & ⋯ & {a}_{xy}\end{matrix} ] ⊙ {w}_{decay} ( t ) ;$$
wherein D_{A}(t) denotes the temporal encoding matrix; a denotes an encoded value of a feature at row i and column j of an alarm event, and a priority level decreases from top-left to bottom-right; and w_{decay}(t) denotes the weight value assigned to the historical alarm event.

5. The power grid fault diagnosis method based on the time constraints and the improved Time-ConvNeXt network according to claim 1, wherein in the step S2, the improved Time-ConvNeXt network comprises depthwise separable convolution, layer normalization and a gaussian error linear unit (GELU) activation function.

6. The power grid fault diagnosis method based on the time constraints and the improved Time-ConvNeXt network according to claim 5, wherein the depthwise separable convolution decomposes a standard convolution into a depthwise convolution and a pointwise convolution.

7. The power grid fault diagnosis method based on the time constraints and the improved Time-ConvNeXt network according to claim 5, wherein the GELU activation function is as follows:
$$GELU ( x ) = 0.5 \cdot x \cdot ( 1 + tanh ( \sqrt{\frac{2}{π}} \cdot ( x + 0.044715 {x}^{3} ) ) ) ;$$
wherein GELU(x) denotes an output of the GELU activation function; x denotes an input of the GELU activation function; and tanh denotes a hyperbolic tangent function.

8. The power grid fault diagnosis method based on the time constraints and the improved Time-ConvNeXt network according to claim 1, further comprising: employing a cross-entropy as a loss function of the power grid fault diagnosis model.
